(19) United States
(12) Patent Application Publication
(10) Pub. No.: US 2026/0144060 A1
(43) Pub. Date: May 21, 2026

(54) STACKED FET STRUCTURE WITH THERMALLY CONDUCTIVE LAYER

(71) Applicant: INTERNATIONAL BUSINESS MACHINES CORPORATION, ARMONK, NY (US)

(72) Inventors: Prabudhya Roy Chowdhury, Albany, NY (US); Debarghya Sarkar, Latham, NY (US); Jingyun Zhang, Albany, NY (US); Teresa J. Wu, Rexford, NY (US); Utkarsh Bajpai, Suffern, NY (US); Abir Shadman, Albany, NY (US)

(21) Appl. No.: 18/954,781

(22) Filed: Nov. 21, 2024

(51) Int. Cl. H01L 23/367; H01L 27/06; H01L 27/092; H01L 29/06; H01L 29/423; H01L 29/775; H01L 29/786

(52) U.S. Cl. CPC H10W 40/228; H10D 30/43; H10D 30/6735; H10D 30/6757; H10D 62/121; H10D 84/856; H10D 88/00

(57) ABSTRACT

A microelectronic structure that includes a stacked field-effect-transistor (FET) that includes a lower FET and an upper FET. The lower FET includes a plurality of lower channel layers and the upper FET includes a plurality of upper channel layers. A gate that surrounds the plurality of lower channel layers and surrounds the plurality of upper channel layers. A heat sink located adjacent to and in direct contact with the gate. The heat generated by the upper FET is transferred to the heat sink and then transferred to an underlying.

### BACKGROUND

The present invention generally relates to the field of microelectronics, and more particularly to forming a heat sink for a stacked FET.

Nanosheet is the lead device architecture in continuing CMOS scaling. However, nanosheet technology has shown issues when scaling down such that as the devices becoming smaller and closer together, they are interfering with each other. With the number of devices being fitted in a smaller area it is becoming harder to remove the heat generated by the devices.

### BRIEF SUMMARY

Additional aspects and/or advantages will be set forth in part in the description which follows and, in part, will be apparent from the description, or may be learned by practice of the invention.

A microelectronic structure that includes a stacked field-effect-transistor (FET) that includes a lower FET and an upper FET. The lower FET includes a plurality of lower channel layers and the upper FET includes a plurality of upper channel layers. A gate that surrounds the plurality of lower channel layers and surrounds the plurality of upper channel layers. A heat sink located adjacent to and in direct contact with the gate. The heat generated by the upper FET is transferred to the heat sink and then transferred to an underlying layer.

A microelectronic structure that includes a stacked field-effect-transistor (FET) that includes a lower FET and an upper FET. The lower FET includes a plurality of lower channel layers and the upper FET includes a plurality of upper channel layers. A gate that surrounds the plurality of lower channel layers and surrounds the plurality of upper channel layers. A gate cap located on top of the gate. A heat sink located adjacent to and in direct contact with the gate. The heat sink is in direct contact with a sidewall of the gate cap. The heat generated by the upper FET is transferred to the heat sink and then transferred to an underlying layer.

A microelectronic structure that includes a stacked field-effect-transistor (FET) that includes a lower FET and an upper FET. The lower FET includes a plurality of lower channel layers and the upper FET (US) includes a plurality of upper channel layers. A gate that surrounds the plurality of lower channel layers and surrounds the plurality of upper channel layers. A heat sink located adjacent to and in direct contact with the gate. The heat generated by the upper FET (US) is transferred to the heat sink and then transferred to an underlying layer. The heat sink is comprised of material selected from a group of hexagonal Boron Nitride (hBN), cubic Boron Nitride (cBN), boron arsenide (BA), diamond material, or another suitable material that has a thermal conductivity greater than 100 W/mK.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of a plurality of stacked nanosheet transistors, in accordance with the embodiment of the present invention.

FIG. 2 illustrates cross section Y1 of the gate region after initial processing, in accordance with the embodiment of the present invention.

FIG. 3 illustrates cross section Y2 of the source/drain region after initial processing, in accordance with the embodiment of the present invention.

FIG. 4 illustrates cross section Y1 of the gate region after formation of heat sink trench, in accordance with the embodiment of the present invention.

FIG. 5 illustrates cross section Y2 of the source/drain region after formation of heat sink trench, in accordance with the embodiment of the present invention.

FIG. 6 illustrates cross section Y1 of the gate region after formation of heat sink liner, in accordance with the embodiment of the present invention.

FIG. 7 illustrates cross section Y2 of the source/drain region after formation of heat sink liner, in accordance with the embodiment of the present invention.

FIG. 8 illustrates cross section Y1 of the gate region after removal of excess heat sink liner material and formation of a cut fill layer, in accordance with the embodiment of the present invention.

FIG. 9 illustrates cross section Y2 of the source/drain region after removal of excess heat sink liner material and formation of a cut fill layer, in accordance with the embodiment of the present invention.

FIG. 10 illustrates cross section Y1 of the gate region after addition processing to form additional components, in accordance with the embodiment of the present invention.

FIG. 11 illustrates cross section Y2 of the source/drain region after addition processing to form additional components, in accordance with the embodiment of the present invention.

FIG. 12 illustrates cross section Y1 of the gate region after addition processing to form additional components, in accordance with the embodiment of the present invention.

FIG. 13 illustrates cross section Y2 of the source/drain region after addition processing to form additional components, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. During the operation of the stacked FET the upper FET and the bottom FET generate heat. The heat generated by the upper FET is difficult to dissipate to or directed towards an underlying substrate, where the underlying substrate acts as a heat sink for the stacked FET. A heat transfer bottleneck is formed around a middle isolation layer that separates the upper FET from the bottom FET. This bottleneck is comprised of the limited amount of space located at the edges/end of the middle isolation layer which leads to degraded performance of the stacked FET because of the poor heat removal of the upper FET. The present invention is directed to controlling the removal of heat generated by the upper FET by forming a heat sink liner or a heat sink column in the gate cut. The heat sink liner or heat sink column is comprised of a material that is thermally conductive and electrically insulating. For example, the material can be hexagonal Boron Nitride (hBN), cubic Boron Nitride (cBN), boron arsenide (BA), diamond material, or other suitable materials that are both thermally conductive and electrically insulating. The heat sink liner or the heat sink column extends from the top of the upper FET to the bottom of the bottom FET, meaning that the heat sink liner or heat sink column is the same height as the stacked FET. The heat sink liner or heat sink column will transfer the generated heat from the upper FET to the underlying substrate while bypassing the bottleneck formed by the middle isolation layer and bypassing the bottom FET. A further benefit is that the heat generated by the bottom or lower FET is able to be transferred to the underlying substrate or shallow trench isolation layer through the heat sink liner or heat sink column.

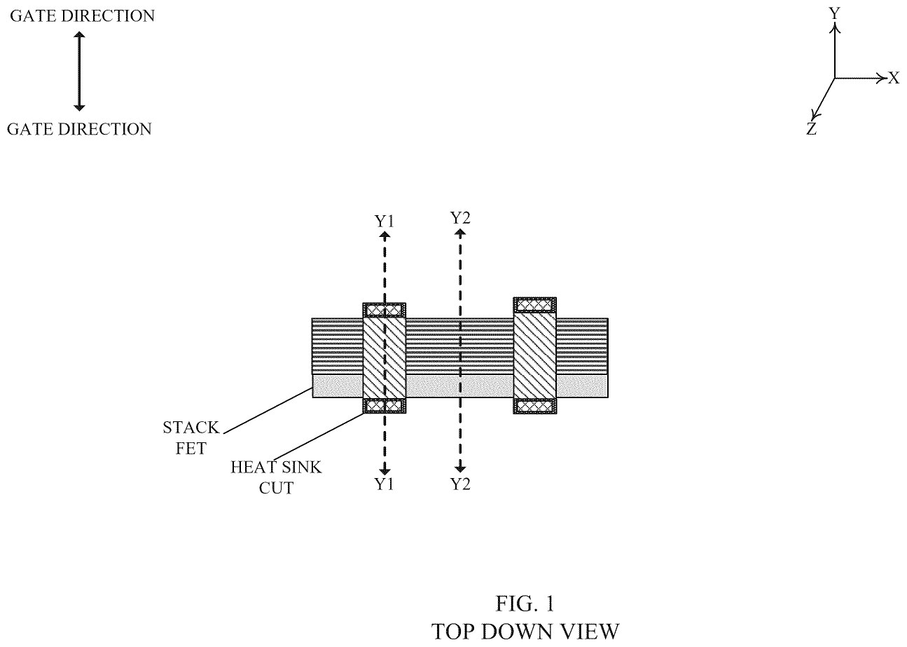

FIG. 1 illustrates a top-down view of multiple stacked FET devices, in accordance with the embodiment of the present invention. Cross section Y1 is a cross section through a gate region of the stacked nanosheet transistors or stacked field-effect-transistors. Cross section Y2 is a cross section through a source/drain region of the stacked nanosheet transistors or stacked field-effect-transistors. Cross-section Y1 and Y2 are parallel to the gate direction.

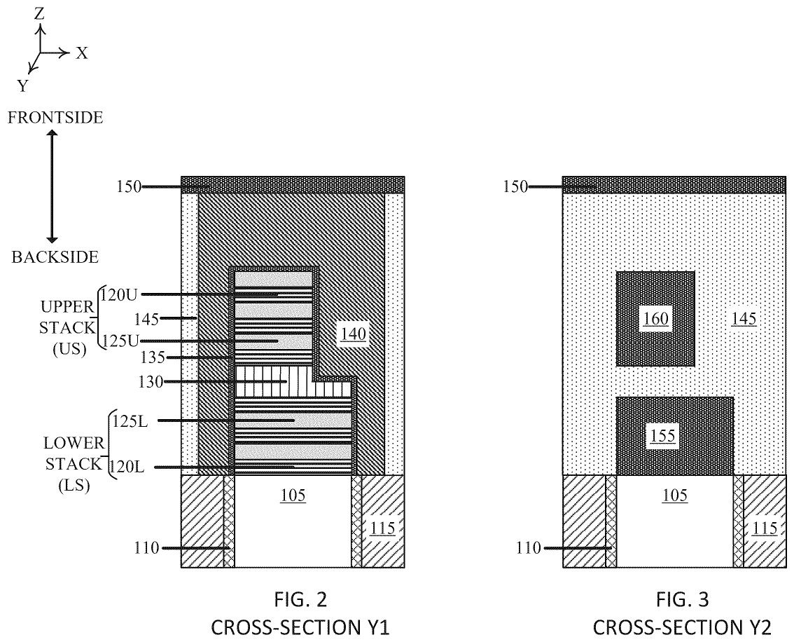

Referring now to FIG. 2, and 3, a structure is shown during an intermediate step of a method of fabricating after initial processing of the stacked FET. FIG. 2 illustrates the gate region where the stacked nanosheet FETs includes a substrate 105, a lower stack (LS), an upper stack (US), a shallow trench isolation liner 110, a shallow trench isolation layer 115, a middle isolation layer 130, a stack liner 135, a dummy gate 140, an interlayer dielectric isolation layer 145, a hardmask 150. The lower stack LS includes a plurality of lower channel layers 125L and a plurality of lower sacrificial layers 120L. The upper stack US includes a plurality of upper channel layers 125U and a plurality of upper sacrificial layers 120U. The plurality of lower and upper channel layers 125L and 125U can be comprised of, for example, Si. The plurality of lower and upper sacrificial layers 120L and 120U can be comprised of, for example, SiGe. The middle isolation layer 130 is located between the upper stack US and the lower stack LS. The stack liner 135 extends around the outside permitter of the lower stack LS, the middle isolation layer 130, and the upper stack US.

The substrate 105 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of semiconductor materials can be used as the semiconductor material of substrate 105. In some embodiments, substrate 105 includes both semiconductor materials and dielectric materials. The semiconductor substrate 105 may also comprise an organic semiconductor or a layered semiconductor such as, for example, Si/SiGe, a silicon-on-insulator or a SiGe-on-insulator. A portion or the entire semiconductor substrate 105 may also be comprised of an amorphous, polycrystalline, or monocrystalline. The semiconductor substrate 105 may be doped, undoped or contain doped regions and undoped regions therein.

FIG. 3 illustrates the source/drain region that includes a lower source drain 155 and an upper source/drain 160. The lower source/drain 155 and the upper source/drain 160 are epitaxially grown in the source/drain regions. The source/drain 155 and the upper source/drain 160, can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

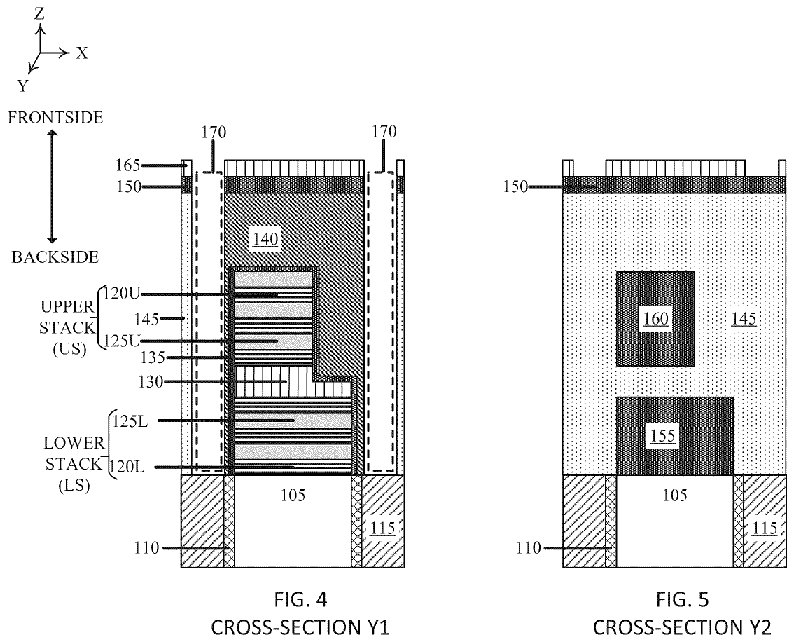

FIGS. 4 and 5 illustrate the processing stage after formation of heat sink trench 170. A lithography layer 165 is formed on top of the hardmask 150. The lithography layer 165 is patterned to form openings that exposed portions of the hardmask 150. The exposed portions of the hardmask 150 located over dummy gate 140 are removed. Portions of dummy gate 140 are selectively removed to form the heat sink trench 170. The heat sink trench 170 extends the entire height of the dummy gate 140, such that the heat sink trench 170 extends higher than the upper stack US. The bottom boundary of heat sink trench 170 can be the shallow trench isolation layer 115 (as illustrated) or the bottom boundary can be comprised of the substrate 105 or a different material. One of vertical sidewalls or vertical boundaries of heat sink trench 170 is comprised of the dummy gate 140 and a second vertical sidewall or vertical boundary of heat sink trench 170 is comprised of the interlayer dielectric isolation layer 145.

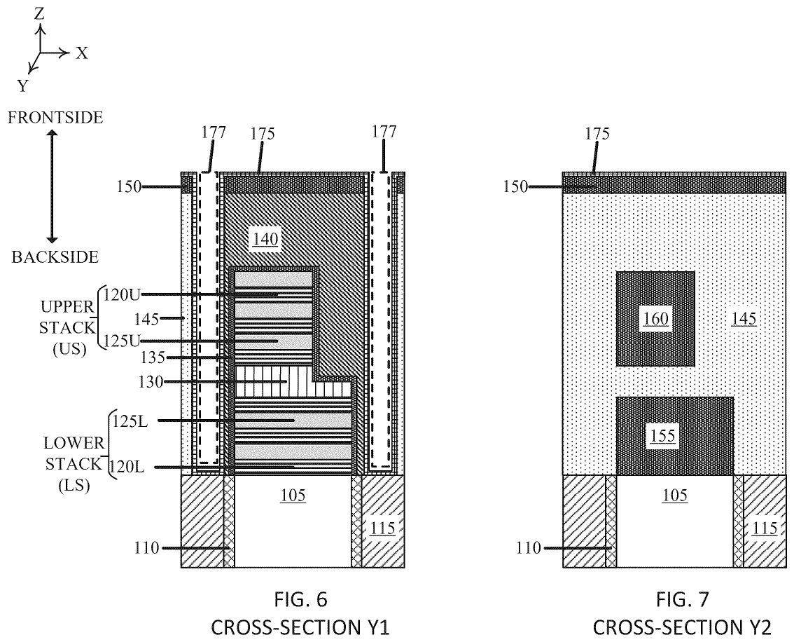

FIGS. 6 and 7 illustrate the processing stage after formation of heat sink liner 175. Lithography layer 165 is removed. A heat sink liner 175 is formed on the exposed surfaces of the hardmask 150 and along the boundaries of the heat sink trench 170 to form the lined heat sink trench 177. The heat sink liner 175 is comprised of a material that is thermally conductive and electrically insulating, where the thermal conductivity of the material is greater than 100 W/mK. For example, the material can be hexagonal Boron Nitride (hBN), cubic Boron Nitride (cBN), boron arsenide (BA), diamond material, or other suitable material that is both thermally conductive and electrically insulating. The heat sink liner 175 can have a thickness in the range of a monolayer to about 5 nanometers. The heat sink liner 175 acts as a side and bottom boundary of the lined heat sink trench 177. The heat sink liner 175 is in contact with a top surface of the shallow trench isolation layer 115 (as illustrated) or it can be contact with the substrate 105 (not shown). The vertical sides of the heat sink liner 175 are in contact with dummy gate 140 or the interlayer dielectric isolation layer 145.

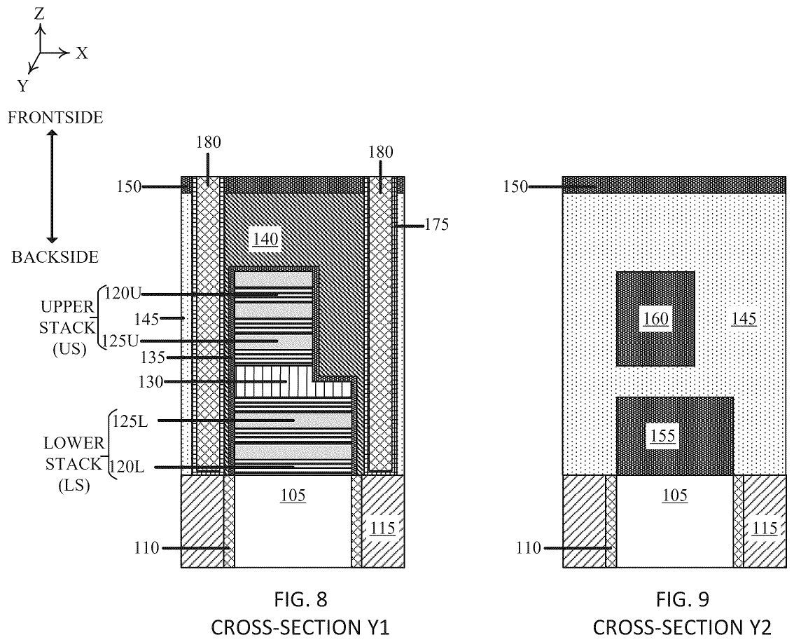

FIGS. 8 and 9 illustrate the processing stage after removal of excess heat sink liner 175 material and formation of a cut fill layer 180. The lined heat sink trench 177 is filled with a cut filled layer 180. The cut fill layer 180 can be comprised of, for example, an oxide, a nitride, or another suitable dielectric material. Excess cut fill layer 180 and excess heat sink liner 175 is removed by a planarization process, for example, chemical mechanical planarization (CMP). The planarization process forms a uniform or flush top surface of the stacked FET.

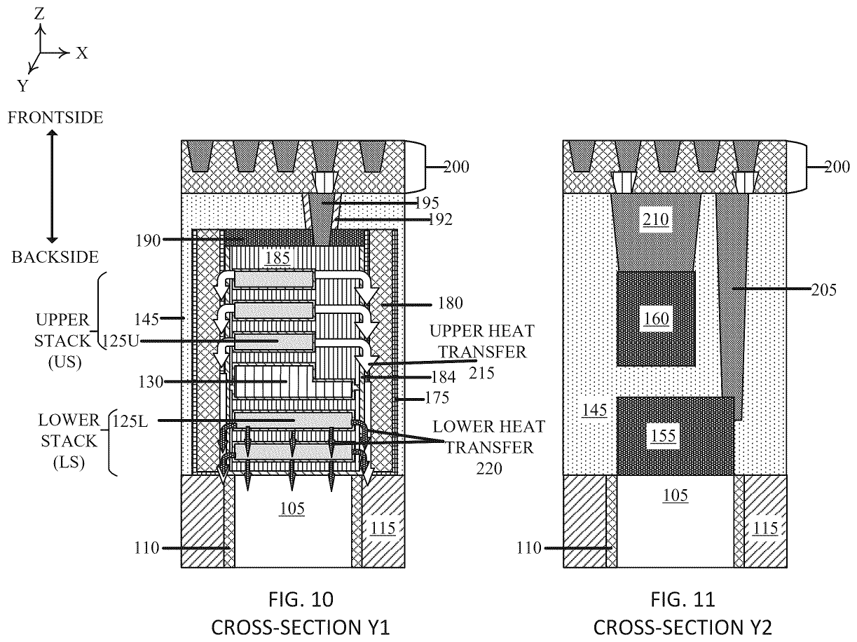

FIGS. 10 and 11 illustrate the processing stage after additional processing stages to form additional components. The hardmask 150, the dummy gate 140, stack liner 135, the lower sacrificial layers 120L, and the upper sacrificial layers 120U are removed. The removal of these layers creates space for the formation of gate 185. Prior to the formation of gate 185 an optional gate liner 184 can be formed around the exposed surfaces of the upper and lower channel layers 125L, 125U, the middle isolation layer 130 and along the sidewall of the heat sink liner 175. Gate 185 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W. Gate cap 190 is formed on top of gate 185. A common sidewall of the heat sink liner 175 is in contact with the side of gate 185 and the side of gate cap 190. The heat sink liner 175 extends past the top surface of gate 185. Additional interlayer dielectric isolation layer 145 material is added to increase the height of the layer on top of the stacked FET. Trenches (not shown) are formed in the interlayer dielectric isolation layer 145 and gate cap 190. These trenches (not shown) can be lined with contact liner 192 and are filled with a conductive material to form gate contact 195, an upper source/drain contact 210, and a lower source/drain contact 205. An interconnect 200 is formed on top of the interlayer dielectric isolation layer 145 and on top of gate contact 195, upper source/drain contact 210, and lower source/drain contact 205. The interconnect 200 can be comprised of one or more layers, one or more metal lines, and one or more vias to make the necessary connections to gate contact 195, upper source/drain contact 210, and lower source/drain contact 205.

During the operation of the stacked FET heat will be generated by the upper stack US FET and the lower stack LS FET. The heat generated from the upper stacked US FET will be transferred laterally to the heat sink liner 175 as illustrated by arrows 215. The generated heat is then transferred via the heat sink liner 175 to the shallow trench isolation layer 115 (as illustrated) or to the underlaying substrate 105. The heat generated by the lower stack LS FET can be transferred directly downwards to substrate 105 and can be transferred laterally to the heat sink liner 175 as illustrated by arrows 220.

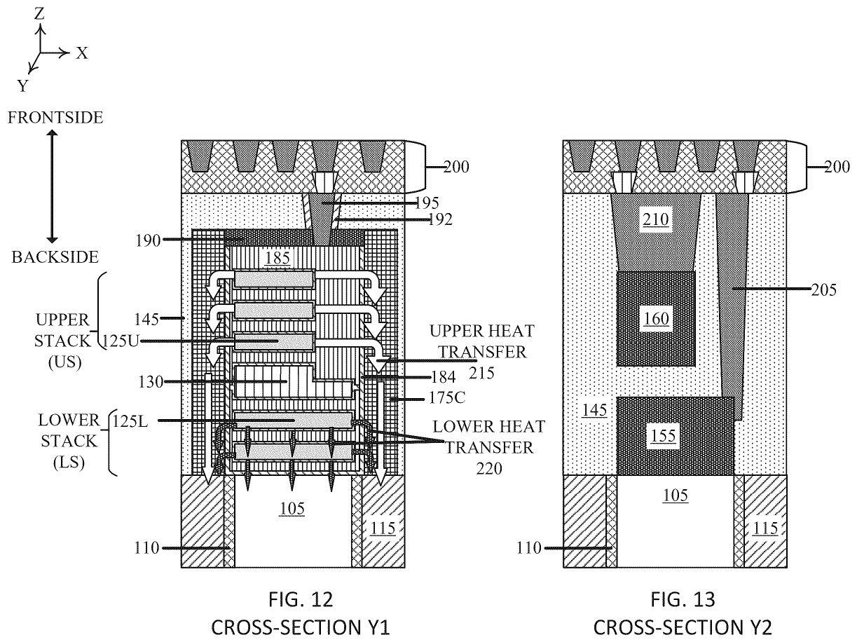

FIGS. 12 and 13 illustrate the processing stage after the formation of additional components in a scenario that is slightly different than the one illustrated in FIGS. 10 and 11. The difference between the figures is the cut fill layer 180 and heat sink liner 175 have been replaced with a heat sink column 175C. The heat sink column 175C was formed by filling the entire heat sink trench 170 with the thermal conductive and electrical insulating material, where the thermal conductivity of the material is greater than 100 W/mK. For example, the thermally conductive and electrically insulating material can be hexagonal Boron Nitride (hBN), cubic Boron Nitride (cBN), boron arsenide (BA), diamond material, or other suitable material that is both thermally conductive and electrically insulating. The heat sink column 175C forms a solid vertical column to transmit the heat generated by the stacked FET to the shallow trench isolation layer 115 or an underlying substrate 105. The thickness of the heat sink column 175C is dependent on the width/dimensions of the heat sink trench 170. The heat sink column 175C can include airgaps (not shown) contain within the column. The heat sink column 175C extends past the top surface of gate 185.

A microelectronic structure that includes a stacked field-effect-transistor (FET) that includes a lower FET (LS) and an upper FET (US). The lower FET (LS) includes a plurality of lower channel layers 125L and the upper FET (US) includes a plurality of upper channel layers 125U. A gate 185/184 that surrounds the plurality of lower channel layers 125L and surrounds the plurality of upper channel layers 125U. A heat sink 175, 175C located adjacent to and in direct contact with the gate 185/184. The heat generated by the upper FET (US) is transferred to the heat sink 175, 175C and then transferred to an underlying layer (shallow trench isolation layer 115, or underlying substrate 105).

The heat sink 175/175C is comprised of a heat sink liner 175. The heat sink liner 175 has a U-shape profile (see, for example, FIGS. 6, 8, 10) as viewed from a cross-section through the gate region, where the cross-section is parallel to the gate direction. The heat sink liner 175 includes at least two vertical sections and a bottom section to form the U-shape profile (see, for example, FIGS. 6, 8, 10). A fill layer 180 located between the vertical sections of the heat sink liner 175 and on top of the bottom section of the heat sink liner 175, (see, for example, FIGS. 8 and 10). The heat sink liner 175 has a thickness of a monolayer. The heat sink liner 175 has a thickness in a range of about 1 to 5 nanometers. The heat sink liner 175 is comprised of a material that is both electrically insulating and thermally conductive, where the thermal conductivity of the material is greater than 100 W/mK.

A microelectronic structure that includes a stacked field-effect-transistor (FET) that includes a lower FET (LS) and an upper FET (US). The lower FET (LS) includes a plurality of lower channel layers 125L and the upper FET (US) includes a plurality of upper channel layers 125U. A gate 185/184 that surrounds the plurality of lower channel layers 125L and surrounds the plurality of upper channel layers 125U. A gate cap 190 located on top of the gate 185. A heat sink 175, 175C located adjacent to and in direct contact with the gate 185/184. The heat sink 175, 175C is in direct contact with a sidewall of the gate cap 190. The heat generated by the upper FET (US) is transferred to the heat sink 175, 175C and then transferred to an underlying layer (shallow trench isolation layer 115, or underlying substrate 105).

The heat sink 175/175C is comprised of a heat sink liner 175. The heat sink liner 175 has a U-shape profile (see, for example, FIGS. 6, 8, 10) as viewed from a cross-section through the gate region, where the cross-section is parallel to the gate direction. The heat sink liner 175 includes at least two vertical sections and a bottom section to form the U-shape profile (see, for example, FIGS. 6, 8, 10). A fill layer 180 located between the vertical sections of the heat sink liner 175 and on top of the bottom section of the heat sink liner 175, (see, for example, FIGS. 8 and 10). The heat sink liner 175 has a thickness of a monolayer. The heat sink liner 175 has a thickness in a range of about 1 to 5 nanometers. The heat sink liner 175 is comprised of a material that is both electrically insulating and thermally conductive, where the thermal conductivity of the material is greater than 100 W/mK. A top surface of the gate cap 190, a top surface of the heat sink liner 175, and a top surface of the fill layer 180 form a flush top surface.

A microelectronic structure that includes a stacked field-effect-transistor (FET) that includes a lower FET (LS) and an upper FET (US). The lower FET (LS) includes a plurality of lower channel layers 125L and the upper FET (US) includes a plurality of upper channel layers 125U. A gate 185/184 that surrounds the plurality of lower channel layers 125L and surrounds the plurality of upper channel layers 125U. A heat sink 175, 175C located adjacent to and in direct contact with the gate 185/184. The heat generated by the upper FET (US) is transferred to the heat sink 175, 175C and then transferred to an underlying layer (shallow trench isolation layer 115, or underlying substrate 105). The heat sink 175, 175C is comprised of material selected from a group of hexagonal Boron Nitride (hBN), cubic Boron Nitride (cBN), boron arsenide (BA), diamond material, or another suitable material that has a thermal conductivity greater than 100 W/mK.

The heat sink 175, 17C is comprised of a heat sink liner 175, where the heat sink liner 175 surrounds a fill layer 180.

The heat sink 175, 175C is comprised of a heat sink column 175C.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure comprising:
a stacked field-effect-transistor (FET) that includes a lower FET and an upper FET, wherein the lower FET includes a plurality of lower channel layers and the upper FET includes a plurality of upper channel layers;
a gate that surrounds the plurality of lower channel layers and surrounds the plurality of upper channel layers; and
a heat sink located adjacent to and in direct contact with the gate, wherein the heat generated by the upper FET is transferred to the heat sink and then transferred to an underlying layer.

2. The microelectronic structure of claim 1, wherein the heat sink is comprised of a heat sink liner.

3. The microelectronic structure of claim 2, wherein the heat sink liner has a U-shape profile as viewed from a cross-section through a gate region, wherein the cross-section is parallel to the gate direction.

4. The microelectronic structure of claim 3, wherein the heat sink liner includes at least two vertical sections and a bottom section to form the U-shape profile.

5. The microelectronic structure of claim 4, further comprises:
a fill layer located between the vertical sections of the heat sink liner and on top of the bottom section of the heat sink liner.

6. The microelectronic structure of claim 5, wherein the heat sink liner has a thickness of a monolayer.

7. The microelectronic structure of claim 5, wherein the heat sink liner has a thickness in a range of about 1 to 5 nanometers.

8. The microelectronic structure of claim 7, wherein the heat sink liner is comprised of a material that is both electrically insulating and thermally conductive, wherein the thermal conductivity of the material is greater than 100 W/mK.

9. A microelectronic structure comprising:
a stacked field-effect-transistor (FET) that includes a lower FET and an upper FET, wherein the lower FET includes a plurality of lower channel layers and the upper FET includes a plurality of upper channel layers;
a gate that surrounds the plurality of lower channel layers and surrounds the plurality of upper channel layers;
a gate cap located on top of the gate; and
a heat sink located adjacent to and in direct contact with the gate, wherein the heat sink is in direct contact with a sidewall of the gate cap, wherein the heat generated by the upper FET is transferred to the heat sink and then transferred to an underlying layer.

10. The microelectronic structure of claim 9, wherein the heat sink is comprised of a heat sink liner.

11. The microelectronic structure of claim 10, wherein the heat sink liner has a U-shape profile as viewed from a cross-section through a gate region, wherein the cross-section is parallel to the gate direction.

12. The microelectronic structure of claim 11, wherein the heat sink liner includes at least two vertical sections and a bottom section to form the U-shape profile.

13. The microelectronic structure of claim 12, further comprises:
a fill layer located between the vertical sections of the heat sink liner and on top of the bottom section of the heat sink liner.

14. The microelectronic structure of claim 13, wherein the heat sink liner has a thickness of a monolayer.

15. The microelectronic structure of claim 13, wherein the heat sink liner has a thickness in a range of about 1 to 5 nanometers.

16. The microelectronic structure of claim 15, wherein the heat sink liner is comprised of a material that is both electrically insulating and thermally conductive, wherein the thermal conductivity of the material is greater than 100 W/mK.

17. The microelectronic structure of claim 16, wherein a top surface of the gate cap, a top surface of the heat sink liner, and a top surface of the fill layer form a flush top surface.

18. A microelectronic structure comprising:
a stacked field-effect-transistor (FET) that includes a lower FET and an upper FET, wherein the lower FET includes a plurality of lower channel layers and the upper FET includes a plurality of upper channel layers;
a gate that surrounds the plurality of lower channel layers and surrounds the plurality of upper channel layers; and
a heat sink located adjacent to and in direct contact with the gate, wherein the heat generated by the upper FET is transferred to the heat sink and then transferred to an underlying layer, wherein the heat sink is comprised of material selected from a group of hexagonal Boron Nitride (hBN), cubic Boron Nitride (cBN), boron arsenide (BA), diamond material, or another suitable material that has a thermal conductivity greater than 100 W/mK.

19. The microelectronic structure of claim 18, wherein the heat sink is comprised of a heat sink liner, wherein the heat sink liner surrounds a fill layer.

20. The microelectronic structure of claim 18, wherein the heat sink is comprised of a heat sink column.
